(19) United States
(12) Patent Application Publication
(10) Pub. No.: US 2008/0100986 A1
(43) Pub. Date: May 1, 2008

(54) Capacitor embedded printed circuit board and manufacturing method thereof

(75) Inventors: Seung Hyun Sohn, Suwon (KR); Yul Kyo Chung, Yongin (KR); Sung Taek Lim, Incheon (KR); Hyung Mi Jung, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 11/907,563

(22) Filed: Oct. 15, 2007

(30) Foreign Application Priority Data
Oct. 27, 2006 (KR) 10-2006-0105229

(51) Int. Cl. H01G 4/00; H01L 21/20

(52) U.S. Cl. 361/301.1; 438/393; 257/E29.001

(57) ABSTRACT

Provided is a method of manufacturing a capacitor embedded printed circuit board. In the method, a laminated body is prepared, including a laminated plate having first and second copper films on both sides thereof, where at least one bottom electrode is provided on at least one side. A dielectric layer is formed on the at least one bottom electrode. A metal layer is formed on a top surface of the dielectric layer where a capacitor is to be formed. A conductive paste layer is formed on at least one region of a top surface of the metal layer, where the conductive paste layer and the metal layer is provided as a top electrode. An insulation resin layers are formed on both sides of the laminated plate, respectively. A conductive via is formed in the insulation resin layer such that it is connected to the conductive paste layer.

### CROSS-REFERENCE TO RELATED APPLICATIONS

This application claims the priority of Korean Patent Application No. 2006-105229 filed on Oct. 27, 2006, in the Korean Intellectual Property Office, the disclosure of which is incorporated herein by reference.

### BACKGROUND OF THE INVENTION

1. Field of the Invention

The present invention relates to a capacitor embedded laminated structure, and more particularly, to a capacitor embedded printed circuit board adapted to improve a binding strength between an electrode and an insulation resin layer and also prevent defects caused by process tolerance in a laser-drilling process, and a manufacturing method thereof.

2. Description of the Related Art

Recently, with an ongoing trend toward miniaturization, high functionality, and high frequency performance of electronic products, there has been introduced an embedded passive device technology where passive devices are not simply mounted on a printed circuit board (PCB) but are embedded into the PCB. This technology is adapted to embed passive devices (generally, half of them are capacitors), which occupy an area of 50% or more of the total surface area, into the PCB or the like, thus contributing to the miniaturization of products and the increase in design flexibility. In addition, this technology improves work reliability by virtue of the decrease in solder connectors, and further it is possible to decrease a parasitic inductance through reduction in noise and connection path.

In particular, a decoupling capacitor is disposed in the vicinity of an integrated circuit (IC) for supplying power and removing noise by a switching operation. Meanwhile, the decoupling capacitor with higher capacitance and lower equivalent series inductance (ELS) is increasingly demanded due to the high-speed performance of an IC chip.

However, a typical embedded decoupling capacitor uses a prepreg type insulation resin layer, of which both sides are attached with copper films, as a dielectric layer. Therefore, there is a limitation in that the embedded decoupling capacitor is hardly used for a desired purpose due to its low capacitance density. Another technology is being developed so as to improve the capacitance density by dispersing ferroelectric fillers into the insulation resin layer and reducing the thickness. This technology does not sufficiently secure the capacitance density per an occupation area yet, and thus the capacitor prepared by this technology is not adapted for the decoupling capacitor.

To overcome such a limitation, researches for developing an embedded thin film capacitor adopting a high dielectric constant thin film have been actively conducted. The embedded thin film capacitor can realize high capacitance and low ESL characteristics because of its small thickness.

The conventional embedded thin film capacitor is prepared by a method including: forming a dielectric layer on a copper film having a thickness of several tens of micrometers or on a bottom electrode deposited on an additional insulation resin of a laminated plate; and forming a top electrode on the dielectric layer. The conventional process of forming the top electrode may be performed using a thin film deposition process such as a sputtering process taking into account of capacitor characteristics.

However, the thin film deposition process requires a long process time and a high fabrication cost in forming a layer to a thickness of about 1 μm. In the case where the top and bottom electrodes are thin, it is difficult to obtain a high Q value due to the increase in loss caused by the electrode and also difficult to apply the thin film deposition process to a fabrication process of PCBs adopting a thick film forming process.

Particularly, to increase the physical binding force between an insulation resin and a conductor such as the copper film and the electrode, a roughening treatment is required upon a surface of a conductor. However, when the electrode has a small thickness, it is impossible to perform the roughening treatment, thus leading to delamination as illustrated in FIG. 1A. This may cause a serious problem in reliability.

Because the dielectric layer and the electrode layer are formed very thinly, they are very weak physically and chemically due to their own characteristics. Therefore, when the thin dielectric layer and the electrode are used for the PCB, they may be susceptible to be damaged because they may be exposed owing to acid or basic solution during a coating process. For these reasons, it is difficult to directly form the top electrode on the dielectric thin film using a coating process or the like.

Furthermore, in order to prevent the damage (see an arrow of FIG. 1B) of the dielectric layer during a laser-drilling process for connecting an interlayer circuit to the thin film capacitor which has been formed previously, it is required an electrode having a thickness of at least several micrometers in consideration of a thickness deviation of the insulation resin layer and a tolerance in the laser-drilling process. As described above, however, it is difficult to form the electrode to a thickness of several micrometers using the thin film deposition process.

### SUMMARY OF THE INVENTION

An aspect of the present invention provides a method of manufacturing a capacitor embedded printed circuit board (PCB) with improved electrode formation process in order to solve the damage and/or the delamination of a dielectric layer caused by a thick film forming process while securing electrical properties of a thin film capacitor.

An aspect of the present invention also provides a capacitor embedded PCB with an improved electrode structure, which can be advantageously used in a thick film forming process while securing superior electrical properties of a thin film capacitor.

According to an aspect of the present invention, there is provided a method of manufacturing a capacitor embedded printed circuit board (PCB), including: preparing a laminated body including a laminated plate having first and second copper films on both sides thereof, at least one bottom electrode being provided on at least one side; forming a dielectric layer on the at least one bottom electrode; forming a metal layer on a region of a top surface of the dielectric layer where a capacitor is to be formed; forming a conductive paste layer on at least one region of a top surface of the metal layer, the conductive paste layer and the metal layer being provided as a top electrode; forming insulation resin layers on both sides of the laminated plate, respectively; and forming a conductive via in the insulation resin layer so as to be connected to the conductive paste layer of the top electrode.

The forming of the conductive paste layer may include forming the conductive paste layer on a substantially entire region of the top surface of the metal layer. In this case, a binding force between the conductive paste and the resin can be sufficiently secured, which makes it possible to improve the biding force several tens of times or greater than that of the conventional art without any additional roughening treatment.

Taking into account of capacitor characteristics and process time, the metal layer of the top electrode may have a thickness ranging from about 50 nm to about 300 nm. The metal layer of the top electrode may include a metal selected from the group consisting of gold (Au), silver (Ag), platinum (Pt) and copper (Cu). The forming of the metal layer of the top electrode may be performed by a physical deposition process or a chemical deposition process.

The conductive paste layer of the top electrode may have a thickness of at least about 2 μm. The conductive paste layer of the top electrode may include Ag or Cu.

Before forming the dielectric layer, the method may further include forming a first metal barrier layer on a top surface of the bottom electrode. In addition, before the forming of the metal layer of the top electrode, the method may further include forming a second metal barrier layer on a top surface of the dielectric layer.

The first and second metal barrier layers may include a metal selected from the group consisting of tantalum (Ta), titanium (Ti), chromium (Cr) and nickel (Ni). The first and second metal barrier layers may have a thickness ranging from about 5 nm to about 100 nm.

The forming of the conductive via in the insulation resin layer may include: forming a via hole in the insulation resin layer using a laser-drilling process, the via hole partially exposing the conductive paste layer; and applying a conductive material to the via hole so as to form an interlayer circuit. This makes it possible to prevent a damage of the dielectric layer caused by a direct contact of the top electrode having the conductive paste layer with laser, a desmear necessarily accompanied by the contact with the laser, and a damage caused by chemical corrosion in a coating process.

An embedded region of the thin film capacitor may be set to an appropriate interlayer region of the PCB. In one implementation, the bottom electrode may be at least one of the first and second copper films of the laminated plate. In alternative implementation, the laminated body may include an additional insulation resin layer provided on one side of the laminated plate, and the bottom electrode may be provided in the embedded region of the thin film capacitor. The method may adopt a combination of these two implementations, if necessary.

According to another aspect of the present invention, there is provided a capacitor embedded PCB manufactured by the above method.

The capacitor embedded PCB includes: a laminated body including a laminated plate having first and second copper films on both sides thereof, at least one bottom electrode being provided on at least one side; a dielectric layer on a top surface of the at least one bottom electrode; a top electrode including a metal layer provided on a region of a top surface of the dielectric layer where a capacitor is to be formed using a thin film deposition process, and a conductive paste layer on at least one region of a top surface of the metal layer; and an insulation resin layer on the laminated body, the insulation resin layer having a conductive via that is connected to the conductive paste layer of the top electrode.

The present invention is not limited to a PCB, but it can be advantageously applied to a manufacturing technology of a thin film capacitor that is embedded in a variety of laminated structures.

According to still another aspect of the present invention, there is provided a method of manufacturing an embedded capacitor, including: preparing a laminated body having a first electrode layer on at least one side thereof; forming a dielectric layer on the first electrode layer; forming a metal layer on the dielectric layer using a thin film deposition process; and forming a conductive paste layer on the metal layer, the conductive paste layer and the metal layer being provided as a second electrode.

In this case, the method may further include forming an insulation layer on at least one side of the laminated body; and forming a conductive via in the insulation layer such that the conductive via is connected to the second electrode layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a micrograph illustrating delamination phenomenon in a conventional capacitor embedded printed circuit board (PCB);

FIG. 1B is a micrograph illustrating a defect caused by a laser-drilling process in a conventional capacitor embedded PCB;

FIGS. 2A through 2E are sectional views illustrating a method of manufacturing an embedded thin film capacitor according to the present invention;

FIG. 3 is a scanning electron microscope (SEM) micrograph illustrating a top electrode of a thin film capacitor prepared according to an embodiment of the present invention; and

FIG. 4 is a graph illustrating capacitances and loss factors of thin film capacitors prepared by various embodiments and comparative examples.

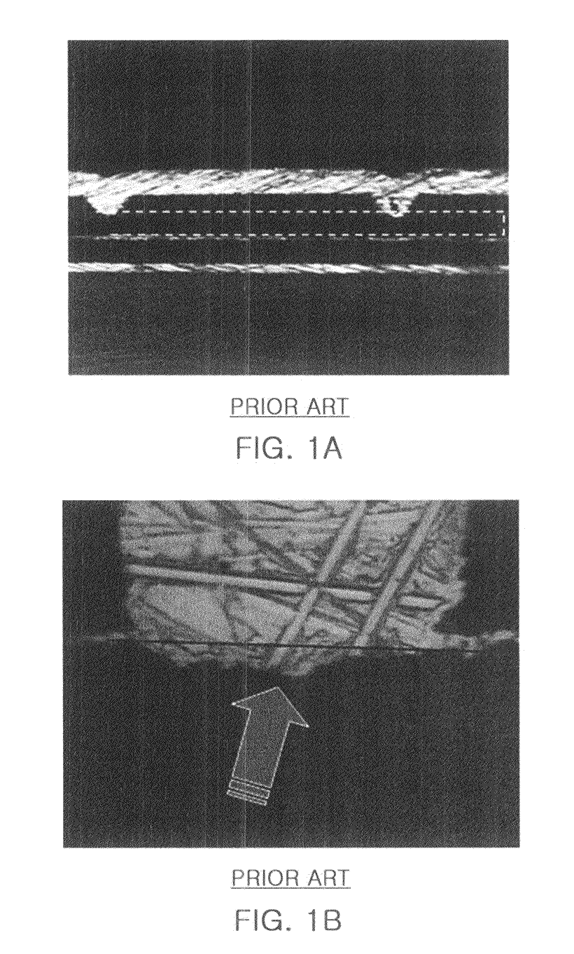

### DETAILED DESCRIPTION OF THE PREFERRED EMBODIMENT

Exemplary embodiments of the present invention will now be described in detail with reference to the accompanying drawings.

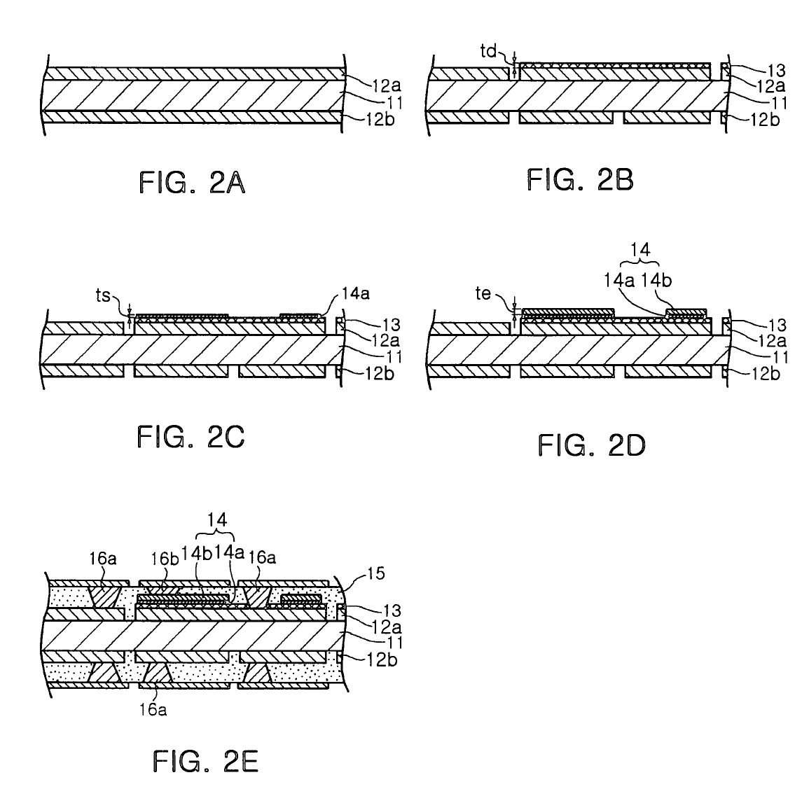

FIGS. 2A through 2E are sectional views illustrating a method of manufacturing an embedded thin film capacitor according to the present invention;

Referring to FIG. 2A, a laminated plate is provided, which includes an insulation resin layer 11 corresponding to a core, and first and second copper films 12a and 12b on both sides of the insulation resin layer 11. Although not shown herein, a metal barrier (not shown) may be formed on a top surface of the first copper film 12a where a dielectric layer (see 13 of FIG. 2B) is to be formed. The barrier layer can improve a binding strength between the dielectric layer 13 and the first copper film 12a, and also prevent copper of the first copper film 12a from diffusing into the dielectric layer 13 to thereby avoid the deterioration of the capacitor characteristics. For example, the metal barrier may include a metal selected from the group consisting of tantalum (Ta), titanium (Ti), chromium (Cr) and nickel (Ni), and may have a thickness ranging from about 5 nm to about 100 nm.

Referring to FIG. 2B, a dielectric layer 13 is formed on the first copper film 12a serving as a bottom electrode. If necessary, the first copper film 12a may be selectively removed with the dielectric layer 13 so as to have a desired circuit pattern. Though the formation of the circuit pattern is implemented at the same time with the dielectric layer 13 in this embodiment, the present invention is not limited to such an implementation. Alternatively, the dielectric layer 13 may be selectively deposited on a target region after forming the desired circuit pattern.

The thickness td of the dielectric layer 13 may be differently designed depending on a required capacitance. Typically, the dielectric layer 13 may have a thickness td ranging from several tens of nanometers to several hundreds of nanometers, and may be formed by a well-known thin film deposition process such as an atomic layer deposition (ALD), a physical deposition process and a chemical deposition process.

Referring to FIG. 2C, by using a thin film deposition process, a metal layer 14a is formed on a top surface of the dielectric layer 13 where a capacitor will be formed. The metal layer 14a adopted in the present invention is provided as a lower layer of the top electrode. The metal layer 14a is formed through the thin film deposition process so as to have a dense microstructure, thus reliably securing properties of the capacitor. To this end, the metal layer 14a may have a thickness ts of at least about 50 nm. In addition, the metal layer 14a may be formed to a thickness of about 300 nm or smaller in consideration of process time and fabrication cost of the thin film deposition process.

The metal layer 14a adopted in this embodiment may include a metal selected from the group consisting of gold (Au), silver (Ag), platinum (Pt) and copper (Cu). Desirably, the metal layer 14a may be formed of Cu. The forming of the metal layer 14a may be performed using a well-known thin film deposition process such as a physical deposition process, e.g., a sputtering process, and a chemical deposition process.

Similar to the process of FIG. 2A as described above, a metal barrier (not shown) may be formed between the dielectric layer 13 and the metal layer 14a to improve a binding strength therebetween and prevent an undesirable diffusion. The metal barrier (not shown) may include a metal selected from the group consisting of Ta, Ti, Cr and Ni, and may be formed to a thickness ranging from about 5 nm to about 100 nm.

Referring to FIG. 2D, a conductive paste layer 14b is formed on the top surface of the metal layer 14a to thereby complete a top electrode 14 of the thin film capacitor. It can be appreciated that the “conductive paste layer 14b” described herein refers to a layer obtained by curing a conductive paste material. The conductive paste layer 14b may be formed to a desirable thickness, e.g., in the range of several micrometers to several tens of micrometers, through a typical thick film forming process. Therefore, the conductive paste layer 14b may serve as a passivation layer that protects the dielectric layer 13 and the metal layer 14a in a process such as a coating process and a laser-drilling process, during which the dielectric layer 13 may be damaged.

In consideration of such an aspect, the conductive paste layer 14b may be formed to a thickness te of at least about 2 μm. Alternatively, the conductive paste layer 14b may have a thickness te of about 100 μm or greater according to circumstances, if an interlayer space allows. More desirably, the conductive paste layer 14b may be in the range of about 5 μm to about 30 μm. The conductive paste layer 14b may include a conductive paste containing Ag or Cu. The conductive paste layer 14b adopted in the present invention may be implemented by a thick film forming process such as a screen printing process.

The conductive paste layer 14b provides such an advantageous merit that its surface has a strong binding force with an insulation resin layer, which will be provided thereon in a subsequent process, in virtue of a resin bond without an additional roughening treatment. For example, in case of pull-off test, while there is an immeasurably weak binding strength between the top electrode and the insulation resin layer according to the conventional deposition, the conductive paste layer 14b adopted in the present invention can exhibit a high binding strength, e.g., 20 kgf/cm² or greater, with the insulation resin layer.

Referring to FIG. 2E, an interlayer circuit including conductive vias 16A and 16B is formed after forming an insulation resin layers 15 on both sides of the laminated plate. Specifically, the conductive vias 16A and 16B may be formed by forming via holes partially exposing the first and second copper films 12a and 12b and the conductive paste layer 14b, respectively, and then filling a conductive material into the via holes through a well-known process such as a coating process. The conductive via 16b is formed such that it is connected to the top electrode 14 of the capacitor. In this case, even though a part of the top electrode 14 is damaged due to process tolerance in a laser-drilling process, it is possible to prevent the damage of the dielectric layer 13 in virtue of the conductive paste layer 14b having a great thickness.

Although the embodiment exemplarily illustrates the laminated plate having the copper films on both sides thereof in which two regions of the first copper film 12a are provided as the top electrode, the present invention is not limited to this so that the inventive method of FIGS. 2A through 2E can be applied to a manufacturing technology of the top electrode for a thin film capacitor embedded in various structures.

For instance, the method of manufacturing the thin film capacitor can be applied to another laminated structure where the second copper film 12b is provided as the bottom electrode or an additional insulation resin layer is provided on one side of the laminated plate. Alternatively, it is possible to realize a PCB by a combination of plurality of laminated structures.

Furthermore, although FIG. 2D exemplarily illustrates that the conductive paste layer 14b is formed on a substantially entire region of the top surface of the metal layer 14a, the conductive paste layer 14b may be provided on a specific region of the metal layer 14a where the conductive via 16b is to be formed because the metal layer 14a can sufficiently serve as the top electrode 14 of the thin film capacitor.

However, since it is difficult to apply the roughening treatment to the metal layer 14a itself, it is desirable that the conductive paste layer 14b is provided in a substantially entire region of the metal layer 14a as illustrated in FIG. 2D in order to improve the binding force with the insulation resin layer 15.

Hereinafter, advantageous effects of the capacitor of the present invention will be more fully illustrated through specific embodiments.

### Embodiment 1

To confirm the improvement effect of thin film capacitor according to the present invention, platinum (Pt) for a bottom electrode was deposited to a thickness of about 150 nm on a silicon wafer using a sputtering process, and nickel (Ni) for a metal barrier layer was deposited to a thickness of about 100 nm on the bottom electrode.

A dielectric thin film of Al₂O₃ was deposited to a thickness ranging from about 70 nm to about 100 nm on the metal barrier layer using an ALD process. Through a sputtering technique using a photoresist process, a Pt metal layer was deposited to a thickness of about 300 nm in a desirable region (e.g., about 25 mm³) where a capacitor was to be formed. Thereafter, a conductive paste containing 80% by weight of Ag was applied on a portion of the metal layer having about an area of 2 mm³ in consideration of an area where the conductive vias were to be formed. Afterwards, the conductive paste was cured for about an hour at about 180° C. to form a conductive paste layer having a thickness of about 15 μm, thus obtaining a thin film capacitor (referred to as sample A).

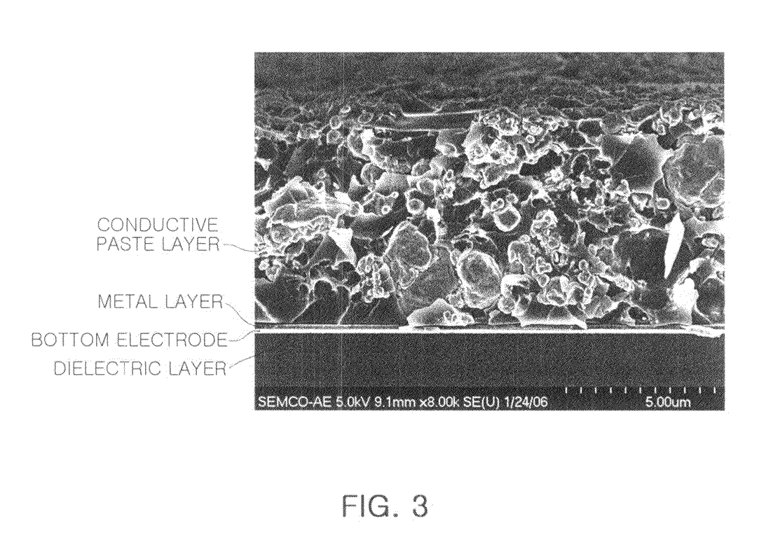

FIG. 3 is a scanning electron microscope (SEM) micrograph illustrating the top electrode of the thin film capacitor prepared according to this embodiment of the present invention. It can be observed that the thin film capacitor includes the top electrode provided with the thin metal layer and the very thick conductive paste layer thereon.

### Embodiment 2

A thin film capacitor (referred to as sample B) of the second embodiment was prepared according to the same process and conditions as those of the foregoing embodiment except that the conductive paste was applied on an entire region of the Pt metal layer and then cured to form the conductive paste layer.

### Comparative Example 1

A thin film capacitor (referred to as sample C) of the comparative example 1 was prepared by the same process and conditions as those of the foregoing embodiments except that the top electrode was prepared by forming only the Pt metal layer without the conductive paste layer like the conventional art.

### Comparative Example 2

A thin film capacitor (referred to as sample D) of the comparative example 1 was prepared by the same process and conditions as those of the foregoing embodiments except that the top electrode was prepared by forming only the conductive paste layer on the dielectric layer without the Pt metal layer.

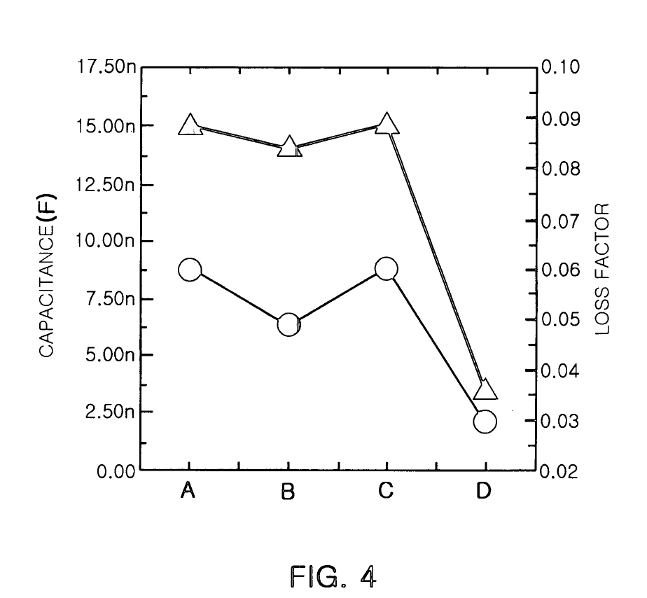

To compare characteristics of the thin film capacitors prepared by the embodiments 1 and 2 and the comparative examples 1 and 2, capacitances and loss factors are measured at 10 MHz, which will be shown in FIG. 4.

Referring to FIG. 4, the thin film capacitor D of the comparative example 2 where the top electrode is provided with only the conductive paste layer exhibits a low loss factor, but its capacitance is extremely small. Accordingly, it can be observed that the thin film capacitor D of the comparative example 2 cannot be used as a thin film capacitor with reliability. That is, since the conductive paste layer does not have a dense microstructure with resin existing between metals, the thin film capacitor D cannot exhibit a required capacitance in case the where the conductive paste layer is used as the top electrode directly contacting the thin film dielectric. On the contrary, the thin film capacitors A and B of the embodiments 1 and 2 exhibit the same capacitances and loss factors as that of the comparative example 1. In particular, the thin film capacitor B of the embodiment 2 where the conductive paste is applied to the entire surface of the metal layer exhibits a relatively low loss factor. This result can be easily understood from the fact that the thin film capacitor D of the comparative example 2 exhibits the lowest resistance loss when only the conductive paste is used as the top electrode.

Although it is exemplarily illustrated that the present invention is applied to the PCB and the manufacturing method thereof, it can be appreciated by a person of ordinary skill in the art that the present invention can be usefully applied to other structures having an embedded thin film capacitor.

According to the present invention, a top electrode of an embedded thin film capacitor is provided with a metal layer densely deposited on an underlying dielectric layer, and a conductive paste layer thickly provided on the metal layer, thus reliably maintaining electrical properties of the capacitor. Furthermore, it is possible to effectively solve the damage of the dielectric layer and/or delamination which may be caused in a thick film forming process of a PCB.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a capacitor embedded printed circuit board (PCB), the method comprising:
preparing a laminated body comprising a laminated plate having first and second copper films on both sides thereof, at least one bottom electrode being provided on at least one side;
forming a dielectric layer on the at least one bottom electrode;
forming a metal layer on a region of a top surface of the dielectric layer where a capacitor is to be formed;
forming a conductive paste layer on at least one region of a top surface of the metal layer, the conductive paste layer and the metal layer being provided as a top electrode;
forming insulation resin layers on both sides of the laminated plate, respectively; and
forming a conductive via in the insulation resin layer so as to be connected to the conductive paste layer of the top electrode.

2. The method of claim 1, wherein the forming of the conductive paste layer comprises forming the conductive paste layer on a substantially entire region of the top surface of the metal layer.

3. The method of claim 1, wherein the metal layer of the top electrode has a thickness ranging from about 50 nm to about 300 nm.

4. The method of claim 1, wherein the metal layer of the top electrode comprises a metal selected from the group consisting of gold (Au), silver (Ag), platinum (Pt) and copper (Cu).

5. The method of claim 1, wherein the forming of the metal layer of the top electrode is performed by a physical deposition process or a chemical deposition process.

6. The method of claim 1, wherein the conductive paste layer of the top electrode has a thickness of at least about 2 μm.

7. The method of claim 1, wherein the conductive paste layer of the top electrode comprises Ag or Cu.

8. The method of claim 1, further comprising, before the forming of the dielectric layer, forming a first metal barrier layer on a top surface of the bottom electrode.

9. The method of claim 1, further comprising, before the forming of the metal layer of the top electrode, forming a second metal barrier layer on a top surface of the dielectric layer.

10. The method of claim 8 or 9, wherein at least one of the first and second metal barrier layers comprises a metal selected from the group consisting of tantalum (Ta), titanium (Ti), chromium (Cr) and nickel (Ni).

11. The method of claim 8 or 9, wherein at least one of the first and second metal barrier layers has a thickness ranging from about 5 nm to about 100 nm.

12. The method of claim 1, wherein the forming of the conductive via in the insulation resin layer comprises:
forming a via hole in the insulation resin layer using a laser-drilling process, the via hole partially exposing the conductive paste layer; and
applying a conductive material to the via hole so as to form an interlayer circuit.

13. The method of claim 1, wherein the bottom electrode is at least one of the first and second copper films on the both sides of the laminated plate.

14. The method of claim 1, wherein the laminated body comprises an additional insulation resin layer provided on one side of the laminated plate,
the bottom electrode being formed on the additional insulation resin layer.

15. A capacitor embedded PCB, comprising:
a laminated body comprising a laminated plate having first and second copper films on both sides thereof, at least one bottom electrode being provided on at least one side;
a dielectric layer on a top surface of the at least one bottom electrode;
a top electrode comprising a metal layer provided on a region of a top surface of the dielectric layer where a capacitor is to be formed using a thin film deposition process, and a conductive paste layer on at least one region of a top surface of the metal layer; and
an insulation resin layer on the laminated body, the insulation resin layer comprising a conductive via that is connected to the conductive paste layer of the top electrode.

16. The capacitor embedded PCB of claim 15, wherein the conductive paste layer is provided on a substantially entire region of the metal layer.

17. The capacitor embedded PCB of claim 15, wherein the metal layer of the top electrode has a thickness ranging from about 50 nm to about 300 nm.

18. The capacitor embedded PCB of claim 15, wherein the metal layer of the top electrode comprises a metal selected from the group consisting of Au, Ag, Pt and Cu.

19. The capacitor embedded PCB of claim 15, wherein the conductive paste layer of the top electrode has a thickness of at least about 2 μm.

20. The capacitor embedded PCB of claim 15, wherein the conductive paste layer of the top electrode comprises Ag or Cu.

21. The capacitor embedded PCB of claim 15, further comprising a first metal barrier layer between the bottom electrode and the dielectric layer.

22. The capacitor embedded PCB of claim 15, further comprising a second metal barrier layer between the dielectric layer and the top electrode.

23. The capacitor embedded PCB of claim 21 or 22, wherein at least one of the first and second metal barrier layers comprises a metal selected from the group consisting of Ta, Ti, Cr and Ni.

24. The capacitor embedded PCB of claim 21 or 22, wherein at least one of the first and second metal barrier layers has a thickness ranging from about 5 nm to about 100 nm.

25. The capacitor embedded PCB of claim 15, wherein the bottom electrode is at least one of the first and second copper films on the both sides of the laminated plate.

26. The capacitor embedded PCB of claim 15, wherein the laminated body comprises an additional insulation resin layer provided on one side of the laminated plate,
the bottom electrode being provided on the additional insulation resin layer.

27. A method of manufacturing an embedded capacitor, the method comprising:
preparing a laminated body having a first electrode layer on at least one side thereof;
forming a dielectric layer on the first electrode layer;
forming a metal layer on the dielectric layer using a thin film deposition process; and
forming a conductive paste layer on the metal layer, the conductive paste layer and the metal layer being provided as a second electrode.

28. The method of claim 27, further comprising:
forming an insulation layer on at least one side of the laminated body; and
forming a conductive via in the insulation layer such that the conductive via is connected to the second electrode layer.
